(19) United States
(12) Patent Application Publication
(10) Pub. No.: US 2007/0241339 A1
(43) Pub. Date: Oct. 18, 2007

(54) LIGHT-EMITTING DIODE WITH LOW THERMAL RESISTANCE

(76) Inventor: JUI-KANG YEN, Taipei City (TW)

Correspondence Address: PATTERSON & SHERIDAN, L.L.P., 3040 POST OAK BOULEVARD, SUITE 1500, HOUSTON, TX, 77056, US

(21) Appl. No.: 11/279,523

(22) Filed: Apr. 12, 2006

(51) Int. Cl. H01L 33/00

(52) U.S. Cl. 257/79

(57) ABSTRACT

A light-emitting diode (LED) structure providing an improved heat transfer path with a lower thermal resistance than conventional LEDs without significantly deviating from the conventional dimensions is described. For some embodiments, a light-emitting diode structure is illustrated that includes a lead frame that is substantially exposed for low thermal resistance by positioning it on the bottom of the light-emitting diode structure. An LED semiconductor chip is electrically and thermally conductively connected to at least one lead of the lead frame for external connection. In some embodiments, a lens or transparent cover plate may cover the LED structure to alter the properties of the emitted light.

### FIELD OF THE INVENTION

The invention relates to the field of light-emitting diode (LED) technology and, more particularly, to LED packaging.

### BACKGROUND OF THE INVENTION

Heat transfer management is a concern for designers of light-emitting diodes (LEDs). When LEDs are driven with high currents, high device temperatures may occur because of insufficient heat transfer from the p-n junction of the semiconductor die to the ambient environment. Such high temperatures can harm the semiconductor and lead to such degradations as accelerated aging, separation of the LED chip from the lead frame, and breakage of bond wires.

In addition to the aforementioned problems, the optical properties of the LED vary with temperature, as well. As an example, the light output of an LED typically decreases with increased junction temperature. Also, the emitted wavelength can change with temperature due to a change in the semiconductor bandgap energy.

The main path for heat dissipation (thermal path) in prior art is from the p-n junction to the lead frame and then through the ends of the leads via heat conduction. At the ends of the leads, heat conduction, convection and radiation serve to transfer heat away from the LED when mounted on a printed circuit board (PCB). There is also a secondary path of heat conduction from the surface of the semiconductor die to the surface of the plastic casing. The problem with this design is that the majority of the lead frame sits within the plastic casing, which acts as a thermal insulator, and the main path for heat dissipation out of the device is limited by the size of the leads. Even designs that have added to the size or number of leads in an effort to promote heat transfer still possess an inherent bottleneck for heat dissipation, as the leads are still sandwiched in the thermally insulative plastic casing.

Accordingly, what is needed is a technique to packaging LEDs that improves heat dissipation.

### SUMMARY OF THE INVENTION

One embodiment of the invention provides a light-emitting diode (LED) structure. The structure generally includes a lead frame having a first lead and a second lead for external connection that is exposed at a bottom portion of the light-emitting diode structure, a light-emitting diode semiconductor chip electrically and thermally conductively connected to the first lead and electrically connected to the second lead, and a housing positioned on top of the first lead and the second lead and providing a recessed volume, wherein at least a portion of the volume is filled with an encapsulation resin.

Another embodiment of the invention provides a different LED structure. The structure generally includes a lead frame having a first lead and a second lead for external connection that is exposed at a bottom portion of the light-emitting diode structure, a light-emitting diode semiconductor chip electrically and thermally conductively connected to the first lead and electrically connected to the second lead, a housing positioned on top of the first lead and the second lead and providing a recessed volume, wherein at least a portion of the volume is filled with an encapsulation resin, and a transparent cover plate covering the encapsulation resin.

Another embodiment of the invention provides a different LED structure than either of the previous two embodiments. The structure generally includes a lead frame having a first lead and a second lead for external connection that is exposed at a bottom portion of the light-emitting diode structure, a light-emitting diode semiconductor chip electrically and thermally conductively connected to the first lead and electrically connected to the second lead, a housing positioned on top of the first lead and the second lead and providing a recessed volume, wherein at least a portion of the volume is filled with an encapsulation resin, and a lens covering the encapsulation resin.

### BRIEF DESCRIPTION OF THE DRAWINGS

FIG. 1A is a 3-D image of a low thermal resistance LED according to one embodiment of the invention;

FIG. 1B is a cross-sectional schematic representation of the low thermal resistance LED shown in FIG. 1a;

FIG. 2 is a cross-sectional schematic representation of a low thermal resistance LED according to one embodiment of the invention;

FIG. 3A is a 3-D image of a low thermal resistance LED according to one embodiment of the invention;

FIG. 3B is a cross-sectional schematic representation of the low thermal resistance LED shown in FIG. 3a;

FIG. 4 is a 3-D image of the low thermal resistance LED shown in FIG. 2, but with a cuboidal housing instead of a cylindrical one;

FIG. 5 is a 3-D image of the low thermal resistance LED shown in FIG. 3a, but with a cuboidal housing instead of a cylindrical one; and

FIG. 6 is a 3-D image of the low thermal resistance LED shown in FIG. 5 depicting how the leads can be extended beyond the housing.

### DETAILED DESCRIPTION OF THE PREFERRED EMBODIMENTS

Embodiments of the present invention provide an improved heat transfer path with a lower thermal resistance than conventional LEDs without significantly deviating from the conventional dimensions. For some embodiments, a surface-mountable light-emitting diode structure is provided that includes a lead frame that is substantially exposed for low thermal resistance by positioning it on the bottom of the light-emitting diode structure. A light-emitting diode semiconductor chip is electrically and thermally conductively connected by solder to a first lead of the lead frame for external connection.

The LED chip may be electrically connected through a bond wire to a second lead of the lead frame for external connection. A housing sitting on top of the first and second leads may provide a recessed volume that is filled with an encapsulation resin or a transparent resin and further covered by a transparent cover plate or lens. In this manner, heat may be efficiently conducted from the p-n junction of the semiconductor directly through the first lead which can be heat sunk on a printed circuit board through a large surface plane, for example. For some embodiments, the leads can extend beyond the confines of the housing for even lower thermal resistance.

### An Exemplary LED Structure

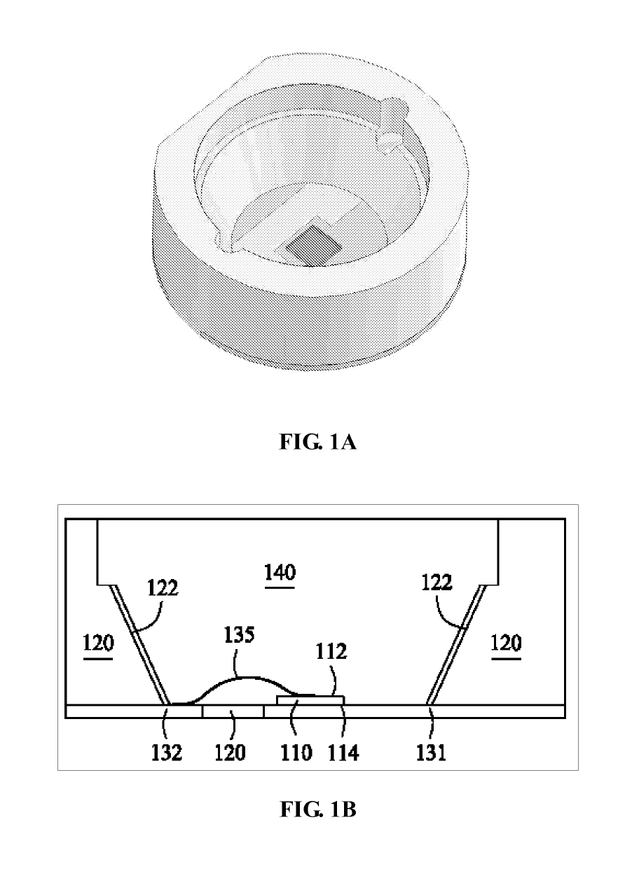

FIG. 1b is a cross-sectional schematic representation of a light-emitting diode (LED) with low thermal resistance, in accordance with one embodiment of the invention. A three-dimensional depiction of the LED is shown in FIG. 1a. This schematic shows an LED chip 110 attached to a first lead 131 by metal solder or some other type of suitable heat-conducting material. The LED chip 110 can represent one or more active LED die and may comprise one of several semiconductor materials, such as GaAs, AlGaAs, AlGaP, AlGaInP, GaAsP, GaP, InGaN, AlN, GaN, or AlGaN. To create electrical properties characteristic of a diode, one side of the LED chip 110 is doped with intentional impurities to create a p-doped side (not shown), while an n-doped side (also not shown) is created on another side of the LED chip 110.

The first lead 131 may be intimately connected to the p-doped side of the LED chip 110 for efficient heat transfer immediately away from the LED chip 110. A second lead 132 is electrically connected to the LED chip 110 through a bond wire (not shown), made of a conductive material, such as gold. For some embodiments, the first lead 131 may be made as large as possible (within the dimensions of the LED package) in an effort to allow for greater heat transfer and, in such cases, will typically be larger than the second lead 132.

In any case, the lead frame (consisting of both leads 131,132 and the bond wire) may be positioned at the bottom of the device, which may result in lower thermal resistance and better heat-sinking capability than the prior art. In the illustrated example, the LED is encased in a cylindrical housing 120 composed of an insulating material such as plastic. Inner surfaces of the housing 120 may have a slope to them and may be coated with a reflective material. The recessed volume inside the housing 120 may be filled with an encapsulation resin 140.

As illustrated, a first surface of each of the leads 131,132 may be enclosed in the housing 120, while a second surface of each of the leads 131, 132 may be substantially exposed through (a bottom portion of) the housing. For example, 10-50% or more of the second surface of one or both of the leads 131, 132 may be exposed. This substantial exposure of the lead(s) to the external world (for connection to a PCB or other type of mounting surface) may greatly enhance thermal conductivity.

In other variations of this embodiment of an LED with low thermal resistance, the leads 131, 132 may extend radially beyond the housing 120. In addition, the housing 120 may have a different shape with leads 131, 132 to match (e.g. a hollowed-out rectangular prism with rectangular leads), and these leads 131, 132 may also extend laterally beyond the housing 120.

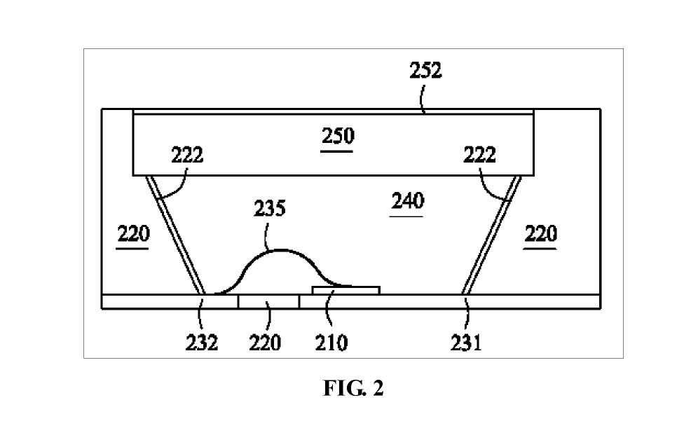

FIG. 2 is a cross-sectional schematic representation of an LED with low thermal resistance, in accordance with another embodiment of the invention. This schematic shows an LED chip 210 attached to a first lead 231 by metal solder or other type of suitable heat-conducting material.

The LED chip 210 can represent one or more active LED die. A second lead 232 is electrically connected to the LED chip 210 through a bond wire (not shown), made of a conductive material, such as gold. For some embodiments, the first lead 231 may be made as large as possible (within the dimensions of the LED package) in an effort to allow for greater heat transfer and, in such cases, will typically be larger than the second lead 232.

In any case, the lead frame (consisting of both leads 231, 232 and the bond wire) may be positioned at the bottom of the device, which may result in lower thermal resistance and better heat-sinking capability than the prior art. In the illustrated example, the LED is encased in a cylindrical housing 220 composed of an insulating material such as plastic. Inner surfaces of the housing 220 may have a slope to them and may be coated with a reflective material.

The recessed volume inside the housing 220 may be filled partway with an encapsulation resin 240 and covered with a transparent cover plate 250. For example, this cover plate 250 may be coated with phosphor to convert one wavelength of light to another wavelength. Another option may be to coat the cover plate 250 with a light absorber to absorb the UV light.

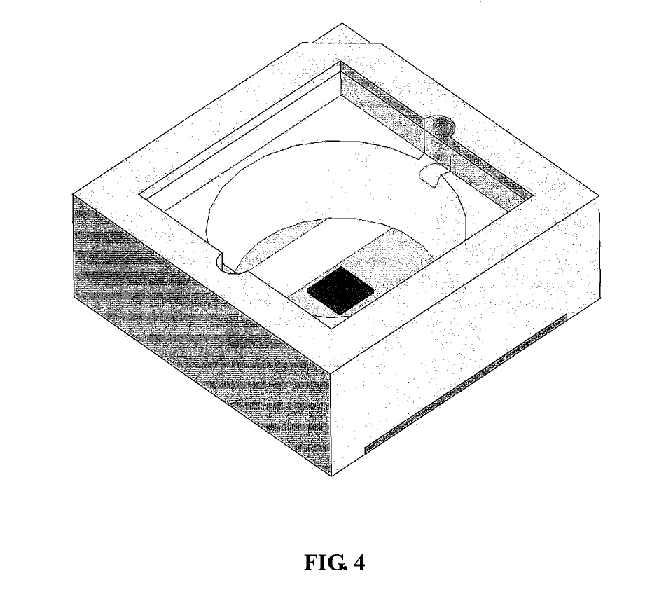

In other variations of this embodiment of an LED with low thermal resistance, the leads 231, 232 may extend radially beyond the housing 220. In addition, the housing 220 may have a different shape with leads 231, 232 to match (e.g. a hollowed-out rectangular prism with rectangular leads as shown in FIG. 4), and these leads 231, 232 may also extend laterally beyond the housing 220.

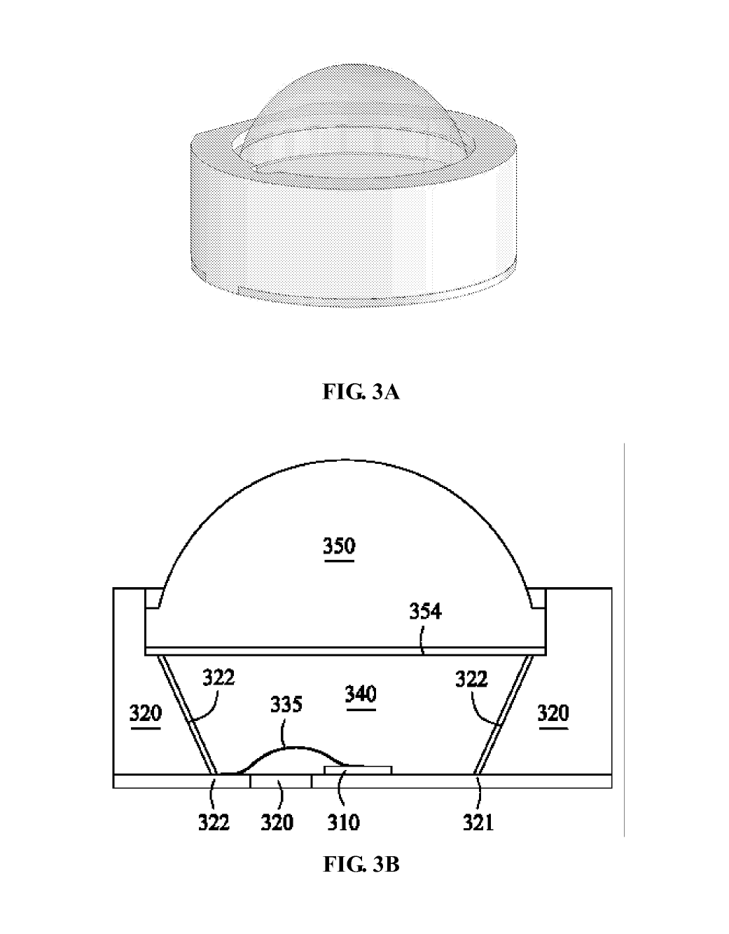

FIG. 3b is a cross-sectional schematic representation of a light-emitting diode (LED) with low thermal resistance, in accordance with another embodiment of the invention. A three-dimensional depiction of the LED is shown in FIG. 3a. This schematic shows an LED chip 310 attached to a first lead 321 by metal solder or some other type of suitable heat-conducting material.

The LED chip 310 can represent one or more active LED die. A second lead 322 is electrically connected to the LED chip 310 through a bond wire (not shown), made of a conductive material, such as gold. For some embodiments, the first lead 321 may be made as large as possible (within the dimensions of the LED package) in an effort to allow for greater heat transfer and, in such cases, will typically be larger than the second lead 322.

In any case, the lead frame (consisting of both leads 331, 332 and the bond wire) may be positioned at the bottom of the device, which may result in lower thermal resistance and better heat-sinking capability than the prior art. In the illustrated example, the LED is encased in a cylindrical housing 320 composed of an insulating material such as plastic. Inner surfaces of the housing 320 may have a slope to them and may be coated with a reflective material. The recessed volume inside the housing 320 is filled partway with an encapsulation resin 340 and covered with a transparent lens 350 that can be used to change the emitting angle of the light. The bottom of the lens 350 may be coated with phosphor to convert one wavelength of light to another wavelength. Another option may be to coat the bottom of the lens 350 with a light absorber to absorb the UV light.

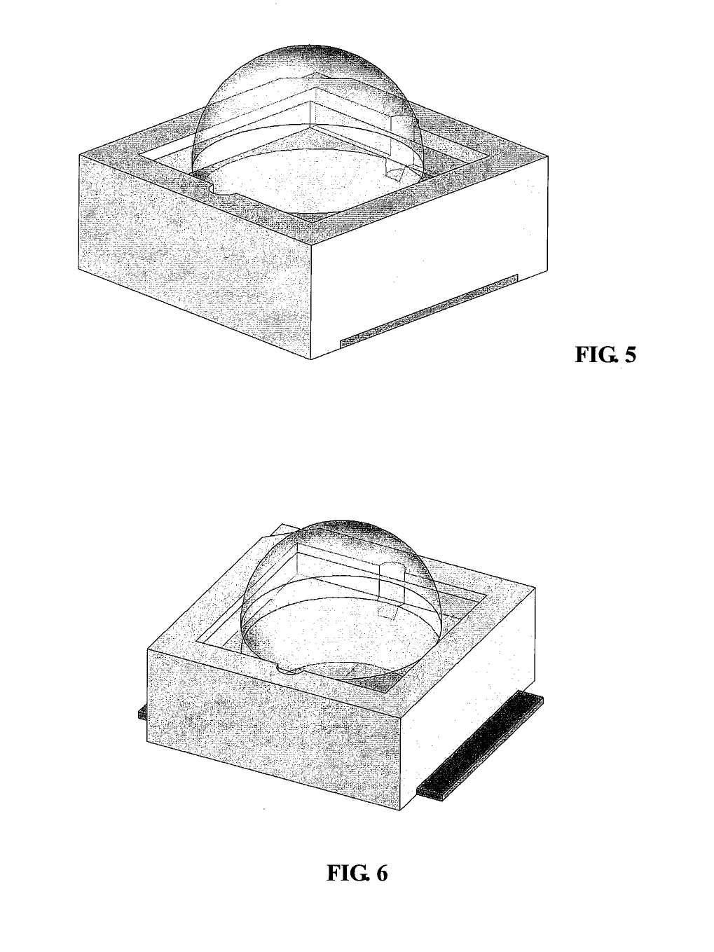

In other variations of this embodiment of an LED with low thermal resistance, the leads 321, 322 may extend radially beyond the housing 320. In addition, the housing 320 may have a different shape with leads 321, 322 to match (e.g. a hollowed-out rectangular prism with rectangular leads as shown in FIG. 5), and these leads 321, 322 may also extend laterally beyond the housing 320 as shown in FIG. 6.

Although the invention is illustrated and described herein as embodied in a surface-mountable light-emitting diode structure, it is nevertheless not intended to be limited to the details shown, since various modifications and structural changes may be made therein without departing from the spirit of the invention and within the scope and range of equivalents of the claims.

1. A light-emitting diode structure comprising:
a housing having a recessed volume;
a light-emitting diode (LED) semiconductor die comprising at least one of GaN, AlN, InGaN, and AlGaN and disposed in the recessed volume of the housing, wherein at least a portion of the recessed volume above the LED semiconductor die is filled with an encapsulation resin; and
a lead frame having a first lead and a second lead for external connection, wherein the first and second leads are exposed through a bottom portion of the housing, the first lead is thermally and electrically coupled to a first polarity of the LED semiconductor die, and the second lead is electrically coupled to a second polarity of the LED semiconductor die.

2. The light-emitting diode structure of claim 1 wherein the first lead is larger than the second lead.

3. The light-emitting diode structure of claim 1 wherein an inner surface defining the recessed volume of the housing is sloped.

4. The light-emitting diode structure of claim 1 wherein an inner surface of the housing is coated with a reflective material.

5. The light-emitting diode structure of claim 1 wherein at least one of the first lead or second lead laterally extends beyond the housing.

6. The light-emitting diode structure of claim 1 wherein the housing is cuboidal.

7. The light-emitting diode structure of claim 1, further comprising
a transparent cover plate covering the encapsulation resin.

8-12. (canceled)

13. The light-emitting diode structure of claim 7 wherein a surface of the transparent cover plate is coated with at least one of a phosphor or a light absorber.

14. The light-emitting diode structure of claim 1, further comprising
a lens covering the encapsulation resin.

15-19. (canceled)

20. The light-emitting diode structure of claim 14 wherein a surface of the lens is coated with at least one of a phosphor or a light absorber.

21. A light-emitting diode structure comprising:
a housing having a recessed volume;
a light-emitting diode (LED) semiconductor die comprising at least one of GaN, AlN, InGaN, and AlGaN and disposed in the recessed volume of the housing, wherein at least a portion of the recessed volume above the LED semiconductor die is filled with an encapsulation resin; and
a lead frame having a first lead and a second lead for external connection, wherein at least 10 percent of a bottom surface of the first lead is exposed through a bottom portion of the housing, the first lead is thermally and electrically coupled to a first polarity of the LED semiconductor die, and the second lead is electrically coupled to a second polarity of the LED semiconductor die.

22. The light-emitting diode structure of claim 21 wherein at least 20 percent of the second surface of the first lead is exposed through the housing.

23. The light-emitting diode structure of claim 21 wherein at least 30 percent of the second surface of the first lead is exposed through the housing.

24. The light-emitting diode structure of claim 21 wherein at least 40 percent of the second surface of the first lead is exposed through the housing.

25. The light-emitting diode structure of claim 21 wherein at least 50 percent of the second surface of the first lead is exposed through the housing.

26. A light-emitting diode structure comprising:
a housing having a recessed volume;
a light-emitting diode (LED) semiconductor die disposed in the recessed volume of the housing; and
a lead frame having first and second leads for external electrical connection to the LED semiconductor die, wherein the first lead is electrically and thermally coupled intimately to a p-doped side of the LED semiconductor die, a first surface of the first lead is enclosed in the housing, and at least 10 percent of a second surface of the first lead is exposed through the housing.

27. The light-emitting diode structure of claim 26 wherein at least 20 percent of the second surface of the first lead is exposed through the housing.

28. The light-emitting diode structure of claim 26 wherein at least 30 percent of the second surface of the first lead is exposed through the housing.

29. The light-emitting diode structure of claim 26 wherein at least 40 percent of the second surface of the first lead is exposed through the housing.

30. The light-emitting diode structure of claim 26 wherein at least 50 percent of the second surface of the first lead is exposed through the housing.

31. The light-emitting diode structure of claim 26 wherein the LED die comprises at least one of GaAs, AlGaAs, AlGaP, AlGaInP, GaAsP, GaP, InGaN, AlN, GaN, or AlGaN.

32. The light-emitting diode structure of claim 26, wherein the first lead is electrically and thermally coupled intimately to the p-doped side of the LED semiconductor die by metal solder.

33. The light-emitting diode structure of claim 26, wherein the first lead is larger than the second lead.

34. The light-emitting diode structure of claim 26, wherein an inner surface of the recessed volume defining the housing is sloped.

35. The light-emitting diode structure of claim 26, wherein an inner surface of the housing is coated with a reflective material.

36. The light-emitting diode structure of claim 26, wherein at least one of the first lead and second lead laterally extends beyond the housing.

37. The light-emitting diode structure of claim 26, wherein the housing is cuboidal.

38. The light-emitting diode structure of claim 26, wherein at least a portion of the recessed volume above the LED semiconductor die is filled with an encapsulation resin.

39. The light-emitting diode structure of claim 38, further comprising a transparent cover plate or a lens covering at least a portion of the encapsulation resin.

40. The light-emitting diode structure of claim 39, wherein a surface of the transparent cover plate is coated with at least one of a phosphor or a light absorber.

41. The light-emitting diode structure of claim 39, wherein a surface of the lens is coated with at least one of a phosphor or a light absorber.

42. The light-emitting diode structure of claim 1, wherein the first lead is thermally and electrically coupled to the first polarity of the LED semiconductor die by metal solder.

43. The light-emitting diode structure of claim 21, wherein the first lead is thermally and electrically coupled to the first polarity of the LED semiconductor die by metal solder.

44. A light-emitting diode structure comprising:
a housing having a recessed volume;
a light-emitting diode (LED) semiconductor die disposed in the recessed volume of the housing, wherein at least a portion of the recessed volume above the LED semiconductor die is filled with an encapsulation resin; and
a lead frame having a first lead and a second lead for external connection, wherein the first and second leads are exposed through a bottom portion of the housing, the first lead is thermally and electrically coupled to a first polarity of the LED semiconductor die by metal solder, and the second lead is electrically coupled to a second polarity of the LED semiconductor die.

45. The light-emitting diode structure of claim 44, wherein an inner surface defining the recessed volume of the housing is sloped.

46. The light-emitting diode structure of claim 44, wherein an inner surface of the housing is coated with a reflective material.

47. The light-emitting diode structure of claim 44, further comprising a transparent cover plate or a lens covering at least a portion of the encapsulation resin.

48. The light-emitting diode structure of claim 47, wherein a surface of the transparent cover plate is coated with at least one of a phosphor or a light absorber.

49. The light-emitting diode structure of claim 47, wherein a surface of the lens is coated with at least one of a phosphor or a light absorber.
